(19) United States
(12) Patent Application Publication
(10) Pub. No.: US 2021/0305229 A1
(43) Pub. Date: Sep. 30, 2021

(54) DISPLAY DEVICE AND AMBIENT LIGHT SENSOR THEREOF

(71) Applicant: EMINENT ELECTRONIC TECHNOLOGY CORP. LTD., Hsin-Chu (TW)

(72) Inventors: KAO-PIN WU, New Taipei City (TW); YI-YUNG CHEN, New Taipei City (TW); CHAN-PENG LO, Taichung City (TW)

(21) Appl. No.: 17/210,036

(22) Filed: Mar. 23, 2021

Related U.S. Application Data
(60) Provisional application No. 63/001,544, filed on Mar. 30, 2020.

(30) Foreign Application Priority Data
Jan. 19, 2021 (TW) 110101925

(51) Int. Cl. H01L 25/18; H01L 27/144; H01L 51/52

(52) U.S. Cl. CPC H01L 25/18; H01L 51/5281; H01L 27/1443

(57) ABSTRACT

A display device comprises an organic light emitting diode (OLED) display panel, an upper linear polarizer, and an ambient light sensor. The upper linear polarizer is disposed over the OLED display panel. The ambient light sensor is disposed beneath the OLED display panel. The ambient light sensor includes a substrate, a first sensing element, a second sensing element, a first lower linear polarizer, and a second lower linear polarizer. The first sensing element senses light to generate a first sensing value. The first lower linear polarizer is disposed between the OLED display panel and the first sensing element. The second sensing element senses light to generate a second sensing value. The second lower linear polarizer is disposed between the OLED display panel and the second sensing element. The first sensing value and the second sensing value are used to calculate an ambient light intensity.

This application claims priority of Application No. 110101925 filed in Taiwan on 19 Jan. 2021 under 35 U.S.C. § 119; and this application claims priority of U.S. Provisional Application No. 63/001,544 filed on 30 Mar. 2020 under 35 U.S.C. § 119(e); the entire contents of all of which are hereby incorporated by reference.

### BACKGROUND OF THE INVENTION

### Field of the Invention

The present invention relates to a display device, particularly to a display device and an ambient light sensor thereof, which can detect ambient light.

### Description of the Prior Art

A mobile electronic device or a wearable electronic device, which is equipped with a display device, is likely to use an ambient light sensor to detect ambient brightness, whereby to adjust screen brightness. The conventional ambient light sensor is disposed in the perimeter of the screen. However, the screen-to-body ratio is growing higher and higher. Hence, the space around the screen, which is available for an ambient light sensor, becomes smaller and smaller. In the display devices with an organic light-emitting diode (OLED) display panel, an ambient light sensor may be disposed beneath the OLED display panel. However, the ambient light sensor, which is on the backside of the OLED display panel, may also receive light from the OLED display panel, in addition to ambient light. The light from the OLED display panel may cause the ambient light sensor to determine incorrect ambient light intensity.

### SUMMARY OF THE INVENTION

One objective of the preset invention is to provide a display device and an ambient light sensor thereof, which can detect ambient light intensity.

According to the present invention, a display device comprises an organic light emitting diode (OLED) display panel, an upper linear polarizer, and an ambient light sensor. The upper linear polarizer is disposed over the OLED display panel and has a reference polarization direction. The ambient light sensor is disposed beneath the OLED display panel and used to detect the ambient light outside the display device. The ambient light sensor includes a substrate, a first sensing element, a second sensing element, a first lower linear polarizer, and a second lower linear polarizer. The first sensing element is disposed on the substrate for sensing light to generate a first sensing value. The first lower linear polarizer is disposed between the OLED display panel and the first sensing element and covers the first sensing element. The first lower linear polarizer has a first polarization direction. The second sensing element is disposed on the substrate for sensing light to generate a second sensing value. The second lower linear polarizer is disposed between the OLED display panel and the second sensing element and covers the second sensing element. The second lower linear polarizer has a second polarization direction which is different from the first polarization direction. An angle between the first polarization direction and the reference polarization direction is different from an angle between the second polarization direction and the reference polarization direction. The first sensing value and the second sensing value are used to calculate an intensity of the ambient light.

According to the present invention, an ambient light sensor comprises a substrate, a first sensing element, a second sensing element, a first linear polarizer, and a second linear polarizer. The first sensing element is disposed on the substrate for sensing light to generate a first sensing value. The first linear polarizer covers the first sensing element and has a first polarization direction. The second sensing element is disposed on the substrate for sensing light to generate a second sensing value. The second linear polarizer covers the second sensing element and has a second polarization direction which is different from the first polarization direction. The first sensing value and the second sensing value are used to calculate an ambient light intensity.

The display device of the present invention uses the upper linear polarizer, the first lower linear polarizer, and the second lower linear polarizer to control the light sensed by the first sensing element and the second sensing element. According to the first sensing value and the second sensing value, which are respectively sensed by the first sensing element and the second sensing element, the intensity of the ambient light can be determined accurately.

### BRIEF DESCRIPTION OF THE DRAWINGS

FIG. 1 is a sectional view schematically showing a display device according to a first embodiment of the present invention.

FIG. 2 schematically shows an embodiment of the upper linear polarizer, the first lower linear polarizer, and the second lower linear polarizer in FIG. 1.

FIG. 3 is a sectional view schematically showing the ambient light sensor in FIG. 1.

FIG. 4 is a sectional view schematically showing a display device according to a second embodiment of the present invention.

### DETAILED DESCRIPTION OF THE INVENTION

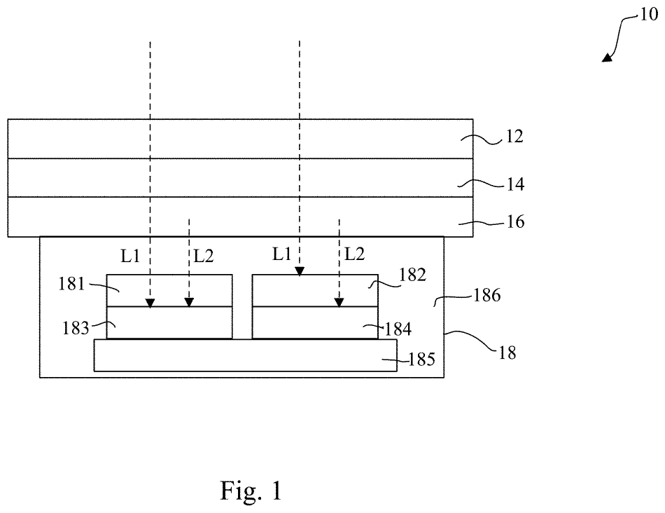

FIG. 1 is a sectional view schematically showing a display device according to a first embodiment of the present invention. As shown in FIG. 1, the display device 10 comprises a glass cover plate 12, an upper linear polarizer 14, an OLED display panel 16, and an ambient light sensor 18. The upper linear polarizer 14 is disposed between the glass cover plate 12 and the OLED display panel 16 and on one side of the OLED display panel 16. The ambient light sensor 18 is disposed on another side of the OLED display panel 16, which is opposite to the upper linear polarizer 14. The upper linear polarizer 14 has a reference polarization direction. When a non-polarized ambient light L1 outside the display device 10 passes through the upper linear polarizer 14, the non-polarized ambient light L1 becomes a linearly polarized light having the reference polarization direction. The OLED display panel 16 is used to show pictures and/or text. The ambient light sensor 18 includes a first lower linear polarizer 181, a second lower linear polarizer 182, a first sensing element 183, a second sensing element 184, and a substrate 185. In one embodiment, the first lower linear polarizer 181, the second lower linear polarizer 182, the first sensing element 183, the second sensing element 184, and the substrate 185 are all integrated in a semiconductor chip. The ambient light sensor 18 has a package structure 186 encapsulating the first lower linear polarizer 181, the second lower linear polarizer 182, the first sensing element 183, the second sensing element 184, and the substrate 185. In other words, in this embodiment, the ambient light sensor 18 is an independent IC (Integrated Circuit) device. The upper region of the package structure 186 has at least one transparent area (not shown in the drawings) corresponding to the first sensing element 183 and the second sensing element 184. The transparent area allows light to enter the ambient light sensor 18. The first lower linear polarizer 181, the second lower linear polarizer 182, the first sensing element 183, and the second sensing element 184 are located below the transparent area. The first sensing element 183 and the second sensing element 184 are disposed on the substrate 185 for sensing light to respectively generate a first sensing value C1 and a second sensing value C2. In one embodiment, the first sensing element 183 or the second light sensing element 184 include at least one light sensor. The light sensor may be but is not limited to be a photodiode. The first lower linear polarizer 181 is disposed between the OLED display panel 16 and the first sensing element 183 and covers the first sensing element 183. The first lower linear polarizer 181 has a first polarization direction. The second lower linear polarizer 182 is disposed between the OLED display panel 16 and the second sensing element 184 and covers the second sensing element 184. The second lower linear polarizer 182 has a second polarization direction. The first polarization direction is different from the second polarization direction. An angle between the first polarization direction and the reference polarization direction is different from an angle between the second polarization direction and the reference polarization direction. There is a processor (not shown in the drawings) in or outside the ambient light sensor 18. The processor can calculate the intensity of the ambient light L1 according to the first sensing value C1 and the second sensing value C2.

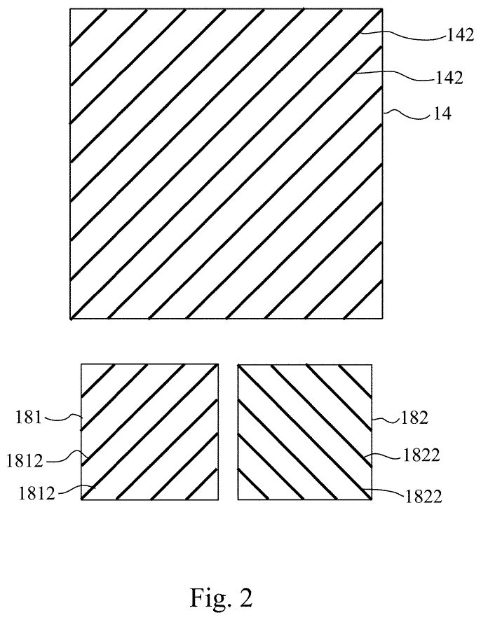

FIG. 2 schematically shows one embodiment of the upper linear polarizer 14, the first lower linear polarizer 181, and the second lower linear polarizer 182 in FIG. 1. The upper linear polarizer 14 has a plurality of parallel metal lines 142 extending along a direction of 45 degrees. Thus, the reference polarization direction of the upper linear polarizer 14 is 45 degrees. The first lower linear polarizer 181 has a plurality of parallel metal lines 1812 extending along a direction of 45 degrees. Thus, the first polarization direction of the first lower linear polarizer 181 is 45 degrees. In other words, the metal lines 1812 are parallel to the first polarization direction. The second lower linear polarizer 182 has a plurality of parallel metal lines 1822 extending along a direction of minus 45 degrees. Thus, the second polarization direction of the second lower linear polarizer 182 is minus 45 degrees. In other words, the metal lines 1822 are parallel to the second polarization direction. In the embodiment shown in FIG. 2, the first polarization direction is parallel to the reference polarization direction. The second polarization direction is perpendicular to the reference polarization direction and the first polarization direction. However, the present invention is not limited by the embodiment shown in FIG. 2. In the embodiment shown in FIG. 2, the upper linear polarizer 14, the first lower linear polarizer 181, and the second lower linear polarizer 182 respectively comprise a plurality of metal lines 142, metal lines 1812 and metal lines 1822. However, the present invention does not limit that the polarization plate must be consisted of metal lines. For example, the upper linear polarizer 14 is consisted of non-metallic lines or another structure in another embodiment.

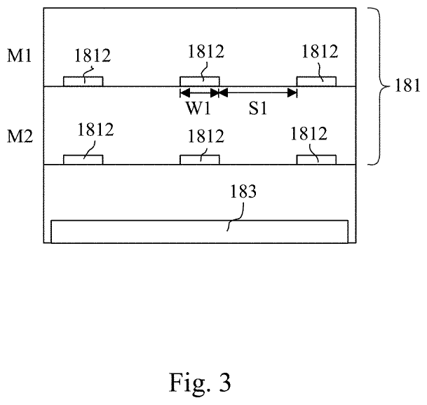

In the embodiment shown in FIG. 1, the first lower linear polarizer 181 and the second lower linear polarizer 182 are inside the ambient light sensor 18. In one embodiment, the metal layers of the ambient light sensor 18 can be used to form the first lower linear polarizer 181 and the second lower linear polarizer 182. FIG. 3 is a sectional view schematically showing the ambient light sensor 18 in FIG. 1. In the embodiment shown in FIG. 3, a plurality of metal lines 1812 of a first metal layer M1 and a second metal layer M2 of the ambient light sensor 18 are used to form the first lower linear polarizer 181. The metal lines 1812 of the first metal layer M1 and the metal lines 1812 of the second metal layer M2 have an identical line width W1 and an identical space S1. In one embodiment, the line width W1 of the metal line 1812 is 0.14 μm to 0.21 μm, and the space S1 between two adjacent metal lines 1812 is 0.15 μm to 0.21 μm. However, the present invention does not limit that the line width W1 and the space S1 must be in the abovementioned ranges. The structure of the second lower linear polarizer 182 is similar to that of the first lower linear polarizer 181 shown in FIG. 3 and the details thereof is omitted for brevity. The first lower linear polarizer 181 and the second lower linear polarizer 182 may be formed by the same metal layer or respectively formed by different metal layers.

Refer to FIG. 1 and FIG. 2. After the ambient light L1 outside the display device 10 passing through the upper linear polarizer 14, the ambient light L1 has the reference polarization direction. As shown in FIG. 2, the reference polarization direction of the upper linear polarizer 14 is parallel to the first polarization direction of the first lower linear polarizer 181 and perpendicular to the second polarization of the second lower linear polarizer 182. Therefore, the ambient light L1 passing the upper linear polarizer 14 cannot pass through the second lower linear polarizer 182 but can pass through the first lower linear polarizer 181. The light L2 coining from the OLED display panel 16 is non-polarized. Therefore, the light L2 can pass through the first lower linear polarizer 181 and the second lower linear polarizer 182. As shown in FIG. 1, the first sensing element 183 can sense the ambient light L1 and the light L2 generated by the OLED display panel 16 to generate a first sensing value C1=L1+L2. The second sensing element 184 can only sense the light L2 generated by the OLED display panel 16 to generate a second sensing C2=L2. Therefore, subtracting the second sensing value C2 from the first sensing value C1 can acquire the intensity of the ambient light L1.

In some embodiments, the first polarization direction of the first lower linear polarizer 181 is not parallel to the reference polarization direction of the upper linear polarizer 14, or the second polarization of the second lower linear polarizer 182 is not perpendicular to the reference polarization direction of the upper linear polarizer 14. However, the intensity of the ambient light L1 can still be acquired in those embodiments. Suppose that the reference polarization direction is neither parallel to the first polarization direction nor perpendicular to the second polarization direction. The first sensing value C1 of the first sensing element 183 and the second sensing value C2 of the second sensing element 184 are respectively expressed by equations EQ-1 and EQ-2:

C1=α1×L1=β1×L2 (EQ-1)

C2=α2×L1=β2×L2 (EQ-2)

wherein α1 is a ratio of the ambient light L1 that is sensed by the first sensing element 183, α2 is a ratio of the ambient light L1 that is sensed by the second sensing element 184, β1 is a ratio of the light L2 is sensed by the first sensing element 183, and 132 is a ratio of the light L2 that is sensed by the second sensing element 184. In the case that the first polarization direction of the first lower linear polarizer 181 is perpendicular to the second polarization direction of the second lower linear polarizer 182, α1+α2=1, and β1+β2=1. According to equations EQ-1 and EQ-2, an equation EQ-3 can be acquired and expressed by

$$L 1 = \frac{C 1 \times β2 - C 2 \times β1}{α1 \times β2 - α2 \times β1} . \qquad ( EQ \text{-} 3 )$$

Therefore, the intensity of the ambient light L1 can be acquired as long as the parameters α1, α2, β1 and β2 are known.

In order to calculate the parameters α1, α2, β1 and β2, the ambient light L1 is controlled to have a fixed intensity (such as 50 Lux), and the OLED display panel 16 is turned off. In this case, the first sensing element 183 will generate a first sensing value:

C1_off=α1×L1 (EQ-4)

and the second sensing element 184 will generate a second sensing value:

C2_off=α2×L1. (EQ-5)

Next, under the same ambient light L1 (such as 50 Lux), the OLED display panel 16 is turned on. In this case, the first sensing element 183 will generate a first sensing value:

C1_on=α1×L1+β1×L2 (EQ-6)

and the second sensing element 184 will generate a second sensing value:

C2_on=α2×L1+β2×L2. (EQ-7)

According to equations EQ-4 to EQ-7, the parameters α1, α2, β1 and β2 are calculating and respectively expressed by

$$\begin{matrix}α1 = \frac{C 1 \_off}{C 1 \_off + C 2 \_off} & ( EQ \text{-} 8 ) \\ α2 = \frac{C 2 \_off}{C 1 \_off + C 2 \_off} & ( EQ \text{-} 9 ) \\ β1 = \frac{C 1 \_on - C 1 \_off}{( C 1 \_on - C 1 \_off ) + ( C 2 \_on - C 2 \_off )} & ( EQ \text{-} 10 ) \\ β2 = \frac{C 2 \_on - C 2 \_off}{( C 1 \_on - C 1 \_off ) + ( C 2 \_on - C 2 \_off )} . & ( EQ \text{-} 11 )\end{matrix}$$

Because the sensing values C1_off, C1_on, C2_off and C2_on are all known values, the parameters α1, α2, β1 and β2 can be acquired. According to the equation EQ-3 and the parameters α1, α2, β1 and β2 acquired beforehand, the display device 10 of the present invention can calculate the intensity of the ambient light L1 according to the first sensing value C1 of the first sensing element 183 and the second sensing value C2 of the second sensing element 184.

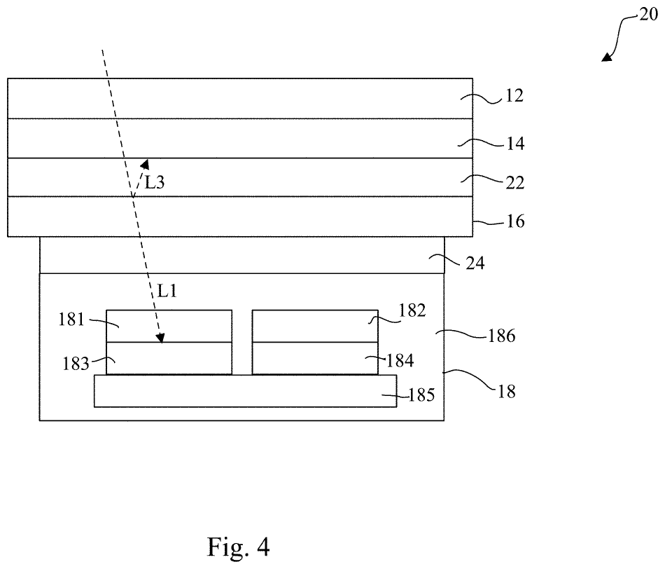

FIG. 4 is a sectional view schematically showing a display device according to a second embodiment of the present invention. Similar to the display device in FIG. 1, the display device 10 in FIG. 4 also includes a glass cover plate 12, an upper linear polarizer 14, an OLED display panel 16, and an ambient light sensor 18. The display device 10 in FIG. 4 further includes an upper quarter-wave plate 22 and a lower quarter-wave plate 24. The upper quarter-wave plate 22 is disposed between the upper linear polarizer 14 and the OLED display panel 16. The lower quarter-wave plate 24 is disposed between the OLED display panel 16 and the ambient light sensor 18 and covers the first lower linear polarizer 181 and the second lower linear polarizer 182. In some embodiments, the lower quarter-wave plate 24 can be integrated into the ambient light sensor 18 so as to form an ambient light sensor with an quarter-wave plate. After the ambient light L1 passes the upper linear polarizer 14, the ambient light L1 becomes a linearly polarized light having the reference polarization direction. After the ambient light L1 having the reference polarization direction passes through the upper quarter-wave plate 22, the ambient light L1 becomes a circularly polarized light. After the circularly polarized light passes through the lower quarter-wave plate 24, the ambient light L1 is restored to the linearly polarized light having the reference polarization direction. While the ambient light L1 is passing through the OLED display panel 16, a portion of the ambient light L1 (ambient light L3) is reflected. After the reflected ambient light L3 passes through the upper quarter-wave plate 22, it becomes a linearly polarized light with a third polarization direction. As the third polarization direction is perpendicular to the reference polarization direction, the reflected ambient light L3 is unlikely to pass through the upper linear polarizer 14. Thus, the contrast of the display device 10 is increased.

The embodiments described above are only to exemplify the present invention but not to limit the scope of the present invention. The persons having ordinary knowledge in the field should be able to make equivalent modifications or variations according to the technical contents disclosed in the specification. However, the modifications made according to the technical schemes mentioned above or the embodiments involving partly or totally replacing the technical characteristics of the present invention would not depart from the spirit of the present invention but would be included by the scope of the present invention.

What is claimed is:

1. A display device, comprising
an organic light-emitting diode (OLED) display panel;
an upper linear polarizer, disposed over the OLED display panel and having a reference polarization direction; and
an ambient light sensor, disposed beneath the OLED display panel, wherein the ambient light sensor includes:
a substrate;
a first sensing element, disposed on the substrate, and sensing light to generate a first sensing value;
a first lower linear polarizer, disposed between the OLED display panel and the first sensing element, covering the first sensing element, and having a first polarization direction;
a second sensing element, disposed on the substrate, and sensing light to generate a second sensing value; and
a second lower linear polarizer, disposed between the OLED display panel and the second sensing element, covering the second sensing element, and having a second polarization direction which is different from the first polarization direction;
wherein an angle between the first polarization direction and the reference polarization direction is different from an angle between the second polarization direction and the reference polarization direction;
wherein the first sensing value and the second sensing value are used to calculate an ambient light intensity.

2. The display device according to claim 1, further comprising:
an upper quarter-wave plate, disposed between the upper linear polarizer and the OLED display panel; and
an lower quarter-wave plate, disposed between the OLED display panel and the ambient light sensor.

3. The display device according to claim 1, wherein the first polarization direction is parallel to the reference polarization direction.

4. The display device according to claim 1, wherein the reference polarization direction and the first polarization direction are 45 degrees.

5. The display device according to claim 1, wherein the first polarization direction is perpendicular to the second polarization direction.

6. The display device according to claim 1, wherein the first lower linear polarizer comprises a plurality of metal layers in the ambient light sensor.

7. The display device according to claim 6, wherein each of the plurality of metal layers has a plurality of metal lines, the plurality of metal lines are parallel to the first polarization direction, each of the plurality of metal lines is 0.14 μm to 0.21 μm in width, and a space between two adjacent ones of the plurality of metal lines is 0.15 μm to 0.21 μm.

8. The display device according to claim 1, wherein the second lower linear polarizer comprises a plurality of metal layers in the ambient light sensor.

9. The display device according to claim 8, wherein each of the plurality of metal layers has a plurality of metal lines, the plurality of metal lines are parallel to the second polarization direction, each of the plurality of metal lines is 0.14 μm to 0.21 μm in width, and a space between two adjacent ones of the plurality of metal lines is 0.15 μm to 0.21 μm.

10. An ambient light sensor, comprising
a substrate;
a first sensing element, disposed on the substrate, and sensing light to generate a first sensing value;
a first linear polarizer, covering the first sensing element, and having a first polarization direction
a second sensing element, disposed on the substrate, and sensing light to generate a second sensing value; and
a second linear polarizer, covering the second sensing element, and having a second polarization direction which is different from the first polarization direction;
wherein the first sensing value and the second sensing value are used to calculate an ambient light intensity.

11. The ambient light sensor according to claim 10, further comprising a quarter-wave plate covering the first linear polarizer and the second linear polarizer.

12. The ambient light sensor according to claim 10, wherein the first polarization direction is 45 degrees.

13. The ambient light sensor according to claim 10, wherein the first polarization direction is perpendicular to the second polarization direction.

14. The ambient light sensor according to claim 10, wherein the first linear polarizer comprises a plurality of metal layers in the ambient light sensor.

15. The ambient light sensor according to claim 14, wherein each of the plurality of metal layers has a plurality of metal lines, the plurality of metal lines are parallel to the first polarization direction, each of the plurality of metal lines is 0.14 μm to 0.21 μm in width, and a space between two adjacent ones of the plurality of metal lines is 0.15 μm to 0.21 μm.

16. The ambient light sensor according to claim 10, wherein the second linear polarizer comprises a plurality of metal layers in ambient light sensor.

17. The ambient light sensor according to claim 16, wherein each of the plurality of metal layers has a plurality of metal lines, the plurality of metal lines are parallel to the second polarization direction, each of the plurality of metal lines is 0.14 μm to 0.21 μm in width, and a space between two adjacent ones of the plurality of metal lines is 0.15 μm to 0.21 μm.
